(19) United States
(12) Patent Application Publication
(10) Pub. No.: US 2024/0362371 A1
(43) Pub. Date: Oct. 31, 2024

(54) TEST SCENARIO GENERATION METHOD, SYSTEM AND DEVICE FOR RISKY LANE-CHANGING TEST OF AUTONOMOUS DRIVING

(71) Applicant: CHANG'AN UNIVERSITY, Xi'an City (CN)

(72) Inventors: Xiangmo Zhao, Xi'an City (CN); Shoucai Jing, Xi'an City (CN); Fei Hui, Xi'an City (CN); Yuyu Zhao, Xi'an City (CN); Lan Yang, Xi'an City (CN)

(73) Assignee: CHANG'AN UNIVERSITY, Xi'an City (CN)

(21) Appl. No.: 18/764,153

(22) Filed: Jul. 4, 2024

(30) Foreign Application Priority Data
Apr. 15, 2024 (CN) CN202410449944.0

(51) Int. Cl. G06F 30/15; G06F 30/27

(52) U.S. Cl. CPC G06F 30/15; G06F 30/27

(57) ABSTRACT

The present disclosure provides a test scenario generation method, system and device for risky lane-changing test of autonomous driving. The method includes: obtaining a real risky lane change trajectory set; generating an adversarial network TimeGAN, and obtaining a constructed risky lane change trajectory generation model Traj-TimeGAN; inputting the data in the real risky lane change trajectory set into Traj-TimeGAN, and outputting a lane change trajectory of a lane change background vehicle with human driving characteristics; analyzing safety constraint conditions of an autonomous driving vehicle and constructing a critical safety distance model for the vehicle; constructing a critical lane change scenario test case, and generating critical lane change test scenarios corresponding to all risky lane change trajectories through scenario generalization. The present disclosure can generate multi-directional lane change entry angles to meet the needs for high-risk testing of autonomous driving.

### CROSS-REFERENCE TO RELATED APPLICATION

This application claims priority to Chinese Patent Application No. 202410449944.0, filed on Apr. 15, 2024 before the China National Intellectual Property Administration, the disclosure of which is incorporated herein by reference in entirety.

### TECHNICAL FIELD

The present disclosure relates to the field of autonomous driving, and in particular, to a test scenario generation method, system and device for risky lane-changing test of autonomous driving.

### BACKGROUND

At present, with the gradual improvement of people's economic wellbeing, the automobile industry has achieved great success. However, the continuous and rapid growth of the number of motor vehicles has led to more and more major traffic accidents. Autonomous vehicles have advantages of fast responses and less driver fatigue, which can greatly reduce the occurrence of traffic accidents. However, in order to permit autonomous driving cars to go on the road, billions of miles of safety tests are required. Limited by various factors such as detection technology, cost and site conditions, traditional road surface tests and regional detection methods can no longer meet the testing requirements of modern autonomous driving vehicles.

Virtual simulation testing methods use digital virtual simulation technology to simulate real test scenarios, which can provide a variety of test scenarios for autonomous driving tests. It has significant advantages in efficiency and cost, and has become an important means of autonomous driving test verification. In addition, using virtual simulation technology to generate high-risk critical scenarios can more effectively improve the autonomous driving tests.

However, the current lane change scenario generation method cannot meet the requirements of high-risk testing of autonomous driving due to great difficulties in generating multi-directional lane change angles when constructing risk-critical lane change scenarios.

### SUMMARY

In order to overcome the shortcoming that it is difficult to generate multi-directional lane change angles for lane change test scenarios, the present disclosure provides a test scenario generation method for risky lane-changing tests during autonomous driving, comprising:
obtaining a real risky lane change trajectory set;
generating an adversarial network TimeGAN, expanding the number of LSTM layers of a long short-term memory network of a generator and discriminator of TimeGAN, and introducing one batch normalization operation for each LSTM layer, and then using a random deactivation Dropout layer to randomly discard half of an output of the LSTM layer, and finally using a fully connected layer for output, and obtaining a probability of each output category through a softmax operation to obtain a constructed risky lane change trajectory generation model Traj-TimeGAN;
inputting the data in the real risky lane change trajectory set into Traj-TimeGAN, and outputting a lane change trajectory of a lane change background vehicle with human driving characteristics;
analyzing safety constraint conditions of an autonomous driving vehicle and constructing a critical safety distance model for the vehicle;
using the critical safety distance model to calculate an initial state of the autonomous driving vehicle under test conditions corresponding to each lane change background vehicle; combining the lane change trajectory of each lane change background vehicle and the initial state of the autonomous driving vehicle under test conditions corresponding to each lane change background vehicle to construct a critical lane change scenario test case, and generating critical lane change test scenarios corresponding to all risky lane change trajectories through scenario generalization.

According to some embodiments of the present disclosure, the batch normalization operation comprises translation parameters and scaling parameters, the LSTM layer comprises an input gate, a forget gate, and an output gate, and the batch normalization operations are performed to weight parameters of the input gate, the forget gate, and the output gate to obtain an optimized generator and discriminator.

According to some embodiments of the present disclosure, it further comprises: replacing a cross entropy loss function of TimeGAN by a mean square error MSE, to obtain the risky lane change trajectory generation model Traj-TimeGAN.

According to some embodiments of the present disclosure, the step of using the critical safety distance model to calculate an initial state of the autonomous driving vehicle under test corresponding to each lane change background vehicle is performed by the following formulas:

$${d}_{min} = {\int }_{0}^{{t}_{C}} {\int }_{0}^{{t}_{C}} {a}_{a v} ( t ) {d}^{2} t - 2 \times l \times cos ( θ ( {t}_{C} ) ) + l \times cos ( θ ( {t}_{T} ) )$$

$${v}_{a v} = {v}_{h v} + {\int }_{0}^{{t}_{C}} {a}_{a v} ( t ) dt$$

$$S = {y}_{lat} ( {t}_{C} ) - l \times sin ( θ ( {t}_{C} ) )$$

$${a}_{a v} ( t ) = \{ \begin{matrix}k \times {a}_{max} \times t , 0 < t \leq {t}_{1} \\ {a}_{max} , {t}_{1} < t \leq {t}_{T}\end{matrix}$$

where, dₘᵢₙ is a minimum safe distance between the autonomous driving vehicle under test and the lane change background vehicle, vₐᵥ is an initial speed of the autonomous driving vehicle under test, S is an initial lateral distance between the autonomous driving vehicle under test and the lane change background vehicle, C is a critical point where the lane change background vehicle and the autonomous driving vehicle under test reach a critical state without collision, t_{C} is a time required for the lane change background vehicle to reach the point C, t is time, d²t represents double integral of acceleration aₐᵥ with respect to t, t_{T} is the moment when the lane change background vehicle and the autonomous driving vehicle under test maintain the same speed, l is a length of the lane change background vehicle, θ(t_{C}) is a lane-changing angle of the autonomous driving vehicle under test at time t_{C}, calculated based on a relative relationship between the lateral positions of the vehicles, similarly, θ(t_{T}) is a lane-changing angle of the autonomous driving vehicle under test at time t_{T}, yₗₐₜ(t_{C}) represents a lateral position of the lane change background vehicle at time t_{C}, vₕᵥ is an average speed of the lane change background vehicle, aₐᵥ(t) is an acceleration of the autonomous driving vehicle under test at time t, k is a slope of acceleration change of the lane change background vehicle, aₘₐₓ represents a maximum braking acceleration of the autonomous driving vehicle under test, and t₁ represents a time for a braking acceleration of the autonomous driving vehicle under test to change from 0 to the maximum braking acceleration.

According to some embodiments of the present disclosure, the numbers of LSTM layers of the generator and the discriminator of the risky lane change trajectory generation model Traj-TimeGAN are both three.

According to some embodiments of the present disclosure, the loss function in the risky lane change trajectory generation model Traj-TimeGAN further comprises a style loss function s_loss, and the style loss function s_loss is expressed as:

$${s\_loss = ‖ D\_s ( {X}_{1 : N} , N ) ) - D\_s ( G ( E ( {X}_{1 : N} , N ) , N ) , N ) ‖}_{2}$$

where, D_s(⋅) is a time discriminator, G(⋅) is a generator, E(⋅) is an encoder, X_{1:N} represents a feature matrix of intermediate states generated for various time steps, N represents a time step, and a length of the feature matrix generated for various time steps is also N, ∥⋅∥₂ represents the two-norm, which is used to represent a length or modulus of a vector.

According to some embodiments of the present disclosure, the loss function in the risky lane change trajectory generation model Traj-TimeGAN further comprises a discriminator loss function d_loss, and the discriminator loss function d_loss is expressed as:

$${d\_loss = ‖ D ( {X}_{1 : N} , N ) ) - D ( G ( E ( {X}_{1 : N} , N ) , N ) , N ) ‖}_{2}$$

where, D(⋅) is a discriminator, G(⋅) is a generator, E(⋅) is an encoder, X_{1:N} represents a feature matrix of intermediate states generated for various time steps, N represents a time step, and a length of the feature matrix generated for various time steps is also N, ∥⋅∥₂ represents the two-norm, which is used to represent a length or modulus of a vector.

The present disclosure further provides a test scenario generation system for risky lane-changing tests during autonomous driving, comprising:
a data set acquisition assembly, configured for obtaining a real risky lane change trajectory set;
a model construction assembly, configured for generating an adversarial network TimeGAN based on time series, expanding the number of LSTM layers of a long short-term memory network of a generator and discriminator of TimeGAN, and introducing one batch normalization operation for each LSTM layer, and then using a random deactivation Dropout layer to randomly discard half of an output of the LSTM layer, and finally using a fully connected layer for output, and obtaining a probability of each output category through a softmax operation to obtain a constructed risky lane change trajectory generation model Traj-TimeGAN;
a lane change vehicle trajectory acquisition assembly, configured for inputting the data in the real risky lane change trajectory set into Traj-TimeGAN, and obtaining a lane change trajectory of a lane change background vehicle with human driving characteristics;
a safety distance model construction assembly, configured for analyzing safety constraint conditions of an autonomous driving vehicle and constructing a critical safety distance model for the vehicle;
a test scenario generation assembly, configured for using the critical safety distance model to calculate an initial state of the autonomous driving vehicle under test corresponding to each lane change background vehicle; combining the lane change trajectory of each lane change background vehicle and the initial state of the autonomous driving vehicle under test corresponding to each lane change background vehicle to construct a critical lane change scenario test case, and generating critical lane change test scenarios corresponding to all risky lane change trajectories through scenario generalization.

The present disclosure further provides a computer device, comprising a memory and a processor, wherein the memory stores a computer program, and the processor is configured to run the computer program in the memory to execute the test scenario generation method for risky lane-changing test of autonomous driving.

The test scenario generation method, system and device for risky lane-changing test of autonomous driving provided by the present disclosure have the following beneficial effects:

The present disclosure makes improvement to the method on the basis of the solution of generation of adversarial network TimeGAN based on time series, expands the number of LSTM layers of the generator and discriminator of TimeGAN to multiple layers, and first introduces a batch normalization operation to each LSTM layer, and then uses the Dropout layer to randomly discard half of the output of the LSTM layer, so as to obtain an improved risky lane change trajectory generation model Traj-TimeGAN; by inputting the data in the real/actual risky lane change trajectory set into the constructed risky lane change trajectory generation model Traj-TimeGAN, it is possible to generate risky lane change trajectories with human driving characteristics. Furthermore, the usage of Traj-TimeGAN with multiple LSTM layers can generate multi-directional lane change entry angles, it constructs high-risk critical lane change test scenarios, and meets the requirements of high-risk testing of autonomous driving.

### BRIEF DESCRIPTION OF THE DRAWINGS

In order to more clearly illustrate the embodiments of the present disclosure and its design scheme, the drawings required for these embodiments will be briefly introduced below. The drawings described below only represent some embodiments of the present disclosure, and other drawings may be obtained by those skilled in the art based on these drawings without creative work.

FIG. 1 is a flow chart of the test scenario generation method for risky lane-changing test of autonomous driving according to an embodiment of the present disclosure;

FIG. 2 is a network structure diagram of TrajTimeGAN;

FIG. 3 is a display diagram of different states of the tested AV and lane change BV;

FIG. 4 is a diagram showing the high-risk critical state of the tested AV and lane change BV;

FIG. 5 shows high-risk critical lane change scenario at different lane change BV speeds;

FIG. 6 is a virtual lane change test scenario built by a virtual traffic simulation platform;

FIG. 7 is a comparison of several loss values of different networks.

### DETAILED DESCRIPTION OF EMBODIMENTS

In order to enable those skilled in the art to better understand the technical solution of the present disclosure and implement it, the present disclosure is described in detail below in conjunction with the accompanying drawings and specific embodiments. The following embodiments are only used to more clearly explain the technical solution of the present disclosure, but should not be used to limit the scope of protection of the present disclosure.

In the description of the present disclosure, it should be understood that the terms “center”, “longitudinal”, “lateral”, “length”, “width”, “thickness”, “up”, “down”, “front”, “rear”, “left”, “right”, “vertical”, “horizontal”, “top”, “bottom”, “inside”, “outside”, “axial”, “radial”, “circumferential” and the like indicate the orientation or position relationship based on the orientation or position relationship shown in the accompanying drawings, such orientation or position relationship is only for the convenience of describing the technical solution of the present disclosure and simplifying the description, rather than indicating or implying that the device or element referred to must have a specific orientation, be constructed and operated in a specific orientation, and therefore they cannot be understood as a limitation on the present disclosure.

In addition, the terms “first”, “second”, etc. are only used for descriptive purposes and cannot be understood as indicating or implying relative importance. In the description of the present disclosure, it should be noted that, unless otherwise clearly specified or limited, the terms “link” and “connect” should be understood in a broad sense, for example, it can be a fixed connection, a detachable connection, or an integrated connection; it can be a mechanical connection or an electrical connection; it can be a direct connection or an indirect connection through an intermediate medium. The specific meanings of the above terms in the present disclosure should be understood by those skilled in the art according to the specific circumstances. In the description of the present disclosure, unless otherwise specified, “multiple” means two or more, which will not be described in detail here.

### Embodiment 1

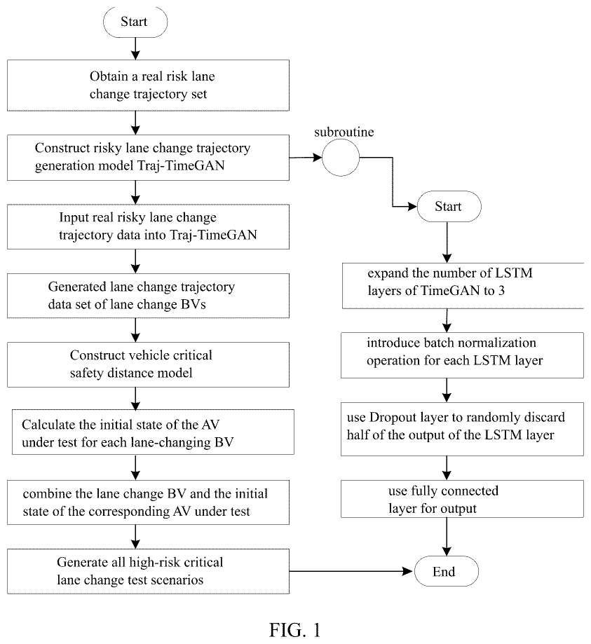

The present disclosure provides a test scenario generation method for risky lane-changing test of autonomous driving, as shown in FIG. 1, comprising the following steps:

Step 1: obtaining a real risky lane change trajectory set.

The real risky lane change trajectory set of the present disclosure selects the lane change trajectories with the lateral acceleration accounting for the top 15% in the same longitudinal speed as the risky lane change trajectory data from the German highD data set, obtains the speed and position information of the vehicle, and screens out 520 risky lane change trajectories. These trajectories are combined into a risky lane change trajectory set, including the lateral position, longitudinal position, speed and other information of the vehicle during driving, and the starting position data in the risky lane change trajectory set is reset to zero. The vehicle speed in the risky lane change trajectory set is between 12 m/s and 45 m/s.

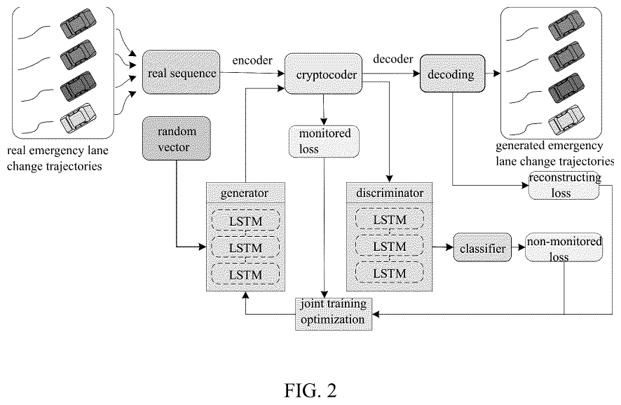

Step 2: The present disclosure makes improvement to the method on the basis of the solution of generation of adversarial network (TimeGAN) based on time series, including adding a batch normalization operation, improving the generator and discriminator, and improving the loss function, to establish an efficient risky lane change trajectory generation model (Traj-TimeGAN) for autonomous driving safety testing, as shown in FIG. 2.

(1) Adding batch normalization operation is to introduce batch normalization (BN) operation in LSTM network. LSTM network is the main component of the generator and discriminator of TimeGAN. LSTM network contains an input gate, a forget gate and an output gate. After adding batch normalization operation to the weight parameters of the three gates, the optimization can be completed. The optimized generator can effectively reduce the loss of the following layers. Batch normalization includes translation parameter and scaling parameter. By modifying the value of the parameters, the range after normalization can be controlled;

(2) The improvement of generator and discriminator is to expand the number of LSTM layers of the generator and discriminator of TimeGAN to multiple layers, and introduce a batch normalization operation to each LSTM layer, and then use a Dropout layer to randomly discard half of the output of the LSTM layer, and finally use a fully connected layer to read the output of the upper layer, and obtain the probability of each category through a softmax operation to obtain a constructed risky lane change trajectory generation model Traj-TimeGAN, the specific process is shown in Table 1. The more the LSTM layers, the stronger the learning ability of the network and the higher the accuracy of the generated data.

TABLE 1
Implementation steps of three-layer LSTM
Algorithm 1: Three-layer LSTM

1. Input layer: The vector length of each time step is 3, and 34 time steps
are continuously input in one training, so the input data is 3*34 each time;
2. The first LSTM to whom BN operation is introduced;
3. Dropout layer: randomly discard half of the output of the LSTM layer;
4. The second LSTM to whom BN operation is introduced;
5. Dropout layer: randomly discard half of the output of the LSTM layer;
6. The third LSTM to whom BN operation is introduced;
7. Fully connected layer: read the output of the upper layer, generate
output through calculation, and obtain the probability of each category
through softmax operation.

(3) Loss function improvement: the original TimeGAN has seven loss values, which are used to show the loss between the generated data and the actual data. Three of them are the main losses, and the rest are other losses in the generation process, this also affects the accuracy of trajectory generation. The original TimeGAN uses cross entropy as the loss function, the cross entropy has disadvantages such as gradient vanishing and sensitivity to noise. The lane change trajectory is a time series, the mean square error (MSE) can measure the difference between the generated value and the actual value and it is insensitive to noise. In addition, MSE is easy to calculate and optimize mathematically. Compared with cross entropy, MSE is more suitable for training time series. In the loss function design, the loss function using cross entropy is replaced with the MSE function, and other loss functions remain as they are.

The style loss function s_loss represents the style difference between the generator output and the target, which can be expressed as:

$${s\_loss = ‖ D\_s ( {X}_{1 : N} , N ) ) - D\_s ( G ( E ( {X}_{1 : N} , N ) , N ) , N ) ‖}_{2}$$

where, D_s(⋅) is a time discriminator, G(⋅) is a generator, E(⋅) is an encoder, X_{1:N} represents a feature matrix of intermediate states generated for various time steps, N represents a time step, and a length of the feature matrix generated for various time steps is also N, ∥⋅∥₂ represents the two-norm, which is used to represent a length or modulus of a vector.

The discriminator loss function d_loss represents the classification accuracy of the discriminator for the real data and generated data, which can be expressed as:

$${d\_loss = ‖ D ( {X}_{1 : N} , N ) ) - D ( G ( E ( {X}_{1 : N} , N ) , N ) , N ) ‖}_{2}$$

where, D(⋅) is a discriminator, G(⋅) is a generator, E(⋅) is an encoder, X_{1:N} represents a feature matrix of intermediate states generated for various time steps, N represents a time step, and a length of the feature matrix generated for various time steps is also N, ∥⋅∥₂ represents the two-norm, which is used to represent a length or modulus of a vector.

Step 3: inputting the data in the real risky lane change trajectory set into Traj-TimeGAN, and obtaining a lane change trajectory of a lane change background vehicle BV with human driving characteristics.

The data in the real risky lane change trajectory set are input into Traj-TimeGAN, and the percentages of the number of the lane change trajectories generated by Traj-TimeGAN and the number of the real lane change trajectories in various average speeds are compared. The results are shown in Table 2. The proportion of data generated by Traj-TimeGAN is similar to that of the real data. Compared with the distribution of real data, the root mean square error of the generated data distribution is 0.069. Therefore, the trajectory generated by Traj-TimeGAN proposed in the present disclosure is highly close to the real scenario, and the number of test scenarios is increased.

TABLE 2
Distribution of average lane change speed lane

| | | |
|---|---|---|
| Average lane | Generated data | Real data |

| change speed | | Proportion | | Proportion |
|---|---|---|---|---|
| (m/s) | Value | (%) | Value | (%) |
| (10, 15] | 988 | 0.19 | 1 | 0.19 |
| (15, 20] | 3 016 | 0.58 | 3 | 0.58 |
| (20, 25] | 21 528 | 4.14 | 21 | 4.04 |
| (25, 30] | 117 312 | 22.56 | 117 | 22.5 |
| (30, 35] | 257 296 | 49.48 | 258 | 49.61 |
| [35, 40) | 99 112 | 19.06 | 99 | 19.04 |
| [40, 45] | 20 748 | 3.99 | 21 | 4.04 |

Step 4: analyzing safety constraint conditions of an autonomous driving vehicle and constructing a critical safety distance model for the vehicle.

The critical safety distance model refers to the situation where the lane change background vehicle (BV) and the autonomous driving vehicle (AV) under test reach a critical state at point C without collision, and at this time the speeds of the two vehicles are equal and the left rear corner of the lane change BV maintains a small distance from the right tangent of the AV under test. Using the critical state of the two vehicles at point C, the initial state of the AV under test, including the relative longitudinal and lateral positions and speeds, is derived. The calculation of the initial state of the AV under test is expressed by the following formula.

$${d}_{min} = {\int }_{0}^{{t}_{C}} {\int }_{0}^{{t}_{C}} {a}_{a v} ( τ ) d τ dt - 2 \times l \times cos ( θ ( {t}_{C} ) ) + l \times cos ( θ ( {t}_{T} ) )$$

$${v}_{a v} = {v}_{h v} + {\int }_{0}^{{t}_{C}} {a}_{a v} ( t ) dt$$

$$S = {y}_{lat} ( {t}_{C} ) - l \times sin ( θ ( {t}_{C} ) )$$

$${a}_{a v} ( t ) = \{ \begin{matrix}k \times {a}_{max} \times t , 0 < t \leq {t}_{1} \\ {a}_{max} , {t}_{1} < t \leq {t}_{T}\end{matrix}$$

The meaning of various items is shown in Table 3.

TABLE 3
Meaning of different items

| Item | Meaning |
|---|---|
| dₘᵢₙ | Minimum safe distance between the tested AV and |
| | the lane change BV |
| vₐᵥ | Initial speed of the tested AV |
| S | Initial lateral distance between the tested AV and |
| | the lane change BV |
| C | Critical point where the lane change BV and the |
| | tested AV reach a critical state without collision |
| t_{C} | Time required for the lane change BV to reach |
| | point C |
| t_{T} | The moment when the two vehicles maintain the |
| | same speed |
| l | Length of the lane change BV |
| θ(t_{C}) | Lane-changing angle of the tested AV at time t_{C} |
| vₕᵥ | Average speed of the lane change BV |
| aₐᵥ(t) | Acceleration of the tested AV at time t |
| θ(t_{C}) | Calculated based on the relative relationship |
| | between the lateral positions of the vehicles |
| k | Slope of acceleration change |

Step 5: using the critical safety distance model to calculate the initial state of the tested autonomous vehicle AV corresponding to each lane change BV.

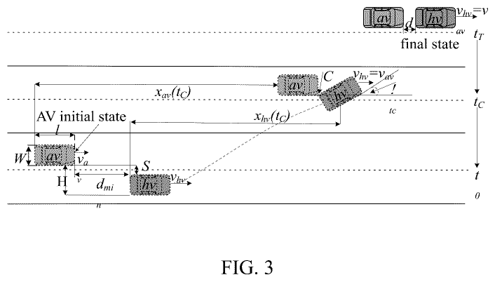

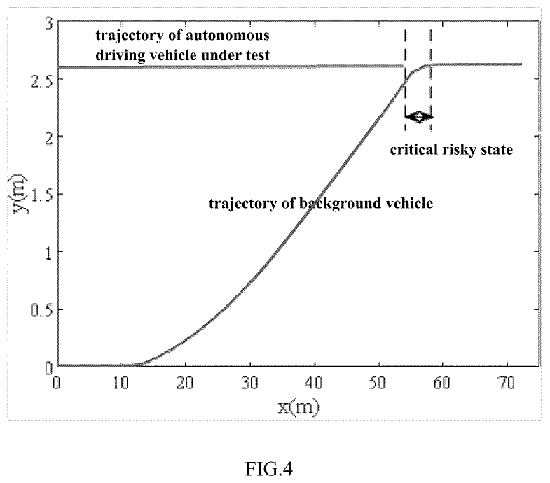

A trajectory is selected from the risky lane change trajectory set as the trajectory of the lane change BV (as shown in FIG. 3), and the initial state of the corresponding AV under test is calculated based on the critical safety distance model. As shown in FIG. 4, the parameters used in the calculation and some experimental settings are shown in Table 4. Substituting into the formulas, we can get:

$${d}_{min} = {\int }_{0}^{{t}_{C}} {\int }_{0}^{{t}_{C}} {a}_{a v} ( τ ) d τ dt - 2 \times l \times cos ( θ ( {t}_{C} ) ) + l \times cos ( θ ( {t}_{T} ) ) = {\int }_{0}^{1.4} {\int }_{0}^{1.4} {a}_{a v} ( τ ) d τ d t - 2 \times 4 \times cos ( θ ( {t}_{C} ) ) + 2 \times cos ( θ ( {t}_{T} ) ) = 11.7$$

$${v}_{a v} = {v}_{h v} + {\int }_{0}^{{t}_{C}} {a}_{a v} ( t ) dt = 26 + {\int }_{0}^{1.4} {a}_{a v} ( t ) dt = 34.4$$

$$S = {y}_{lat} ( {t}_{C} ) - l \times sin ( θ ( {t}_{C} ) ) = 2.4 - 4 \times 0.15 = 1.8$$

TABLE 4
Parameters required for calculating safety distance

| Parameter Meaning | Value | |
|---|---|---|
| Speed vₐᵥ of lane change BV | 26 | m/s |
| Time t to complete lane change | 1.7 | s |
| Time t_{C} to reach critical point C | 1.4 | s |
| Braking and deceleration time period t₂ | 0.2 | s |
| Speed v₁ of lane change background | Average speed of generated lane | |
| vehicle | change trajectory | |
| Length N of real trajectory sequence | 34 | |
| Total number of real trajectories | 520 | |
| Longitudinal distance dₜ of lane | Longitudinal distance of | |
| change | generated lane change trajectory | |
| Vehicle length l | 4 | m |
| Time t of lane change background | Equal to braking time t of tested | |
| vehicle to complete lane change | autonomous driving vehicle | |
| Maximum vehicle braking | 6 | m/s² |

| | |
|---|---|
| acceleration aₘₐₓ | 34 |
| Time step | |

From the above formulas, it can be concluded that the initial longitudinal position, lateral position and speed of the tested AV are 1.8, −11.7 and 34.4 respectively. The tested AV performs emergency braking while the lane change BV performs lane change. When the lane change BV reaches the critical point C, the speed of the tested AV drops to the same speed as the lane change BV and stops braking, the two vehicles just do not collide, which belongs to a high-risk critical lane change scenario.

Step 6: combining the lane change trajectory of each lane change BV and the initial state of the AV under test corresponding to each lane change BV to construct a critical lane change scenario test case, and generating critical lane change test scenarios corresponding to all risky lane change trajectories through scenario generalization.

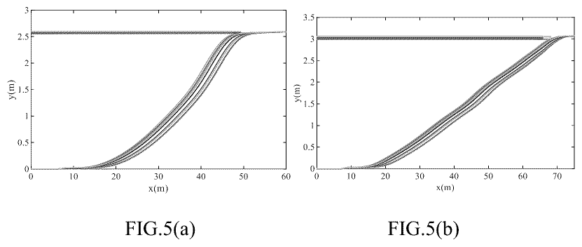

The HighD dataset is used to generate risky lane change trajectories. Each risky lane change trajectory can generate multiple risky lane change trajectories, which are similar to the original risky lane change trajectory, and high-risk critical lane change scenarios with different lane change cut-in angles at the same speed can be constructed. 15 groups of typical high-risk critical lane change scenarios generated by selecting two groups of original lane change trajectories with different speeds are shown in FIG. 5. It can be found that the method proposed in the present disclosure can expand the lane change cut-in angle. Through calculating the minimum safety distance, the two vehicles do not collide when the lane change BV completes the lane change, and maintain a critical safety distance, indicating that the generated lane change scenario belongs to a high-risk critical lane change scenario.

The present disclosure also provides a test scenario generation system for risky lane-changing test of autonomous driving, including a data set acquisition assembly, a model construction assembly, a lane change vehicle trajectory acquisition assembly, a safety distance model construction assembly and a test scenario generation assembly. The data set acquisition assembly is configured for obtaining a real risky lane change trajectory set; the model construction assembly is configured for generating an adversarial network TimeGAN based on time series, expanding the number of LSTM layers of a long short-term memory network of a generator and discriminator of TimeGAN, and introducing one batch normalization operation for each LSTM layer, and then using a random deactivation Dropout layer to randomly discard half of an output of the LSTM layer, and finally using a fully connected layer for output, and obtaining a probability of each output category through a softmax operation to obtain a constructed risky lane change trajectory generation model Traj-TimeGAN; the lane change vehicle trajectory acquisition assembly is configured for inputting the data in the real risky lane change trajectory set into Traj-TimeGAN, and obtaining a lane change trajectory of a lane change background vehicle with human driving characteristics; the safety distance model construction assembly is configured for analyzing safety constraint conditions of an autonomous driving vehicle and constructing a critical safety distance model for the vehicle; the test scenario generation assembly is configured for using the critical safety distance model to calculate an initial state of the autonomous driving vehicle under test corresponding to each lane change background vehicle; combining the lane change trajectory of each lane change background vehicle and the initial state of the autonomous driving vehicle under test corresponding to each lane change background vehicle to construct a critical lane change scenario test case, and generating critical lane change test scenarios corresponding to all risky lane change trajectories through scenario generalization.

Specifically, the lane change test scenario realizes the construction of a virtual simulation traffic platform in the Unity3D game engine. The risky lane change trajectory is saved to the database and interacts with the virtual simulation traffic scenario, and then works as the trajectory of the background vehicle in the virtual simulation traffic platform. The initial state of the tested AV is injected in the same way to complete the test of the autonomous driving vehicle.

The present disclosure also provides a computer device, including a memory and a processor; the memory stores a computer program, and the processor is used to run the computer program in the memory to execute the test scenario generation method for risky lane-changing test of autonomous driving.

### Embodiment 2

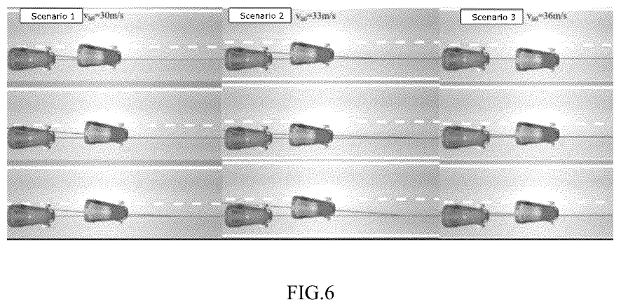

Randomly select three groups of high-risk critical lane change scenarios as test cases, select different speeds of lane change BV respectively, and calculate the initial state of the tested AV according to the collision constraint. As shown in FIG. 6, each group has three high-risk lane change critical scenarios, and for each group it has risky lane change trajectories with different entry angles generated from the same original risky lane change trajectory. In FIG. 6, the black vehicle represents the lane change BV, and the red vehicle represents the tested AV. When the lane change BV changes lanes, the tested AV starts emergency braking until the lane change BV reaches the safety critical point, the speed of the tested AV is reduced to the same speed as the lane change vehicle, and the two vehicles maintain a minimum critical distance.

The experiment compared 520,000 lane change sequences generated by BN-AM-SeqGAN, SeqGAN, and RankGAN. Using the same risky lane change conditions, 414,544, 373,516, and 379,392 risky lane change trajectories that meet the requirements were screened out, as shown in Table 5. As can be seen from Table 5, the effectiveness of the data generated by Traj-TimeGAN is the highest.

TABLE 5
Effectiveness/Validity of data generated by different networks

| | Number of | Effectiveness/ |
|---|---|---|
| Network | matches | Validity |
| Traj-TimeGAN | 520 000 | 100% |
| BN-AM-SeqGAN | 414 544 | 79.72% |
| SeqGAN | 373 516 | 71.83% |
| RankGAN | 379 392 | 72.96% |

The experiment compared the root mean square error of the original data and the generated data. After calculation, 99.27% of the root mean square error of the vehicle position in the lane change direction is less than 0.015, and 98.53% of the root mean square error of the vehicle speed in the driving direction is less than 0.001, indicating that the original data and the generated data are highly similar. In addition, the root mean square errors of the longitudinal speed and lateral position of the lane change trajectories generated by BN-AM-SeqGAN are both greater than 0.1, indicating that the lane change trajectories generated by Traj-TimeGAN are better than the generated results of BN-AM-SeqGAN.

In the generated lane change scenarios, 99.93% of the scenarios in which the tested AV would collide with the lane change BV within 1 second, they all belong to high-risk critical lane change scenarios, indicating that the proposed method in the present disclosure can successfully construct high-risk critical lane change scenarios for autonomous driving testing.

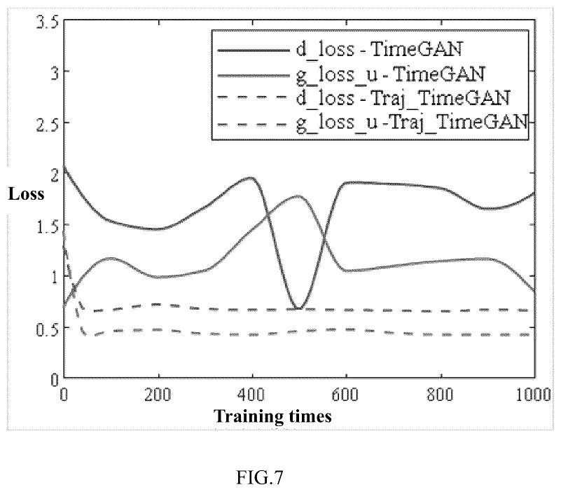

In order to illustrate the improvement of the proposed Traj-TimeGAN in network performance, Traj-TimeGAN was compared with TimeGAN using different networks as generators and discriminators; the two networks were pre-trained the same number of times to generate data. The comparison results are shown in Table 6, where speed represents the lateral speed of the vehicle, position represents the longitudinal position of the vehicle, and coefficient represents the number of vehicle coordinate systems. DeepLSTM includes two layers of LSTM, and DeepLSTM3L includes three layers of LSTM. In Table 6, BN represents BN operation, and the generator and discriminator of Traj-TimeGAN use DeepLSTM 3L after BN. As shown in Table 6, the more LSTM layers in the model, the smaller the root mean square error; in addition, adding BN operation can reduce the root mean square error. The root mean square error of the proposed Traj-TimeGAN is the smallest among all models. The loss value of Traj-TimeGAN is lower than that of TimeGAN, as shown in FIG. 7, which indicates that the proposed method can achieve good generation results.

TABLE 6
Root mean square error results of generators
and discriminators of different networks

| | | RMSE | | | |
|---|---|---|---|---|---|
| TimeGAN | | | | Coef- | Average |
| | Discrim- | Speed | Position | ficient | value |
| Generator | inator | (×10⁻³) | (×10⁻³) | (×10⁻³) | (×10⁻³) |
| LSTM | LSTM | 3.96 | 1.49 | 6.8 | 4.08 |
| LSTM | 2LSTM | 3.42 | 1.28 | 5.55 | 3.42 |
| 2LSTM | 2LSTM | 2.78 | 1.14 | 4.99 | 2.97 |
| LSTM | 3LSTM | 2.41 | 0.84 | 4.88 | 2.71 |
| 2LSTM | 3LSTM | 2.02 | 0.86 | 4.4 | 2.43 |
| 3LSTM | 3LSTM | 1.86 | 0.85 | 4.03 | 2.25 |
| 3LSTM + BN | 3LSTM + BN | 1.37 | 0.85 | 3.47 | 1.90 |

The present disclosure uses an improved time-series generative adversarial network algorithm (Traj-TimeGAN). By inputting real risky lane change trajectory data, risky lane change trajectories with different lane change entry angles with human driving characteristics can be generated. At the same time, the lane change entry angle is expanded, and a critical safety distance model is proposed. According to the different trajectories of lane change BV, the corresponding initial state of the tested autonomous driving vehicle can be calculated, the two vehicles constitute a high-risk critical lane change scenario. After continuous network training and calculation of the minimum safety distance constraint, a high-risk critical lane change scenario for autonomous driving testing can be obtained, thereby achieving the purpose of improving the efficiency of autonomous driving testing.

Vehicle navigation and control systems developed through the inventive method may be implemented in autonomous and assisted navigation of vehicles capable of navigating in a variety of environments, including highway, urban and rural roads, construction sites, emergency detours, parking and mixed driving environments. Vehicles developed with the inventive methods are capable of improved vehicle safety, faster decision times, and optimized routing. Application of the inventive methods to automotive engineering represents an advancement over prior art methods in terms of increasing experimental throughput, precision and accuracy of testing methods in comparison to prior art methods.

The above-mentioned embodiments are only optional specific embodiments of the present disclosure, and the protection scope of the present disclosure is not limited thereto. Any simple change or equivalent replacement of the technical solution that can be obviously obtained by those skilled in the art within the technical scope disclosed by the present disclosure belongs to the protection scope of the present disclosure.

What is claimed is:

1. A test scenario generation method for risky lane-changing tests during autonomous driving, comprising:
obtaining a real risky lane change trajectory set;
generating an adversarial network TimeGAN, expanding the number of LSTM layers of a long short-term memory network of a generator and discriminator of TimeGAN, and introducing one batch normalization operation for each LSTM layer, and then using a random deactivation Dropout layer to randomly discard half of an output of the LSTM layer, and finally using a fully connected layer for output, and obtaining a probability of each output category through a softmax operation to obtain a constructed risky lane change trajectory generation model Traj-TimeGAN;
inputting the data in the real risky lane change trajectory set into Traj-TimeGAN, and outputting a lane change trajectory of a lane change background vehicle with human driving characteristics;
analyzing safety constraint conditions of an autonomous driving vehicle and constructing a critical safety distance model for the vehicle;
using the critical safety distance model to calculate an initial state of the autonomous driving vehicle under test conditions corresponding to each lane change background vehicle; combining the lane change trajectory of each lane change background vehicle and the initial state of the autonomous driving vehicle under test conditions corresponding to each lane change background vehicle to construct a critical lane change scenario test case, and generating critical lane change test scenarios corresponding to all risky lane change trajectories through scenario generalization.

2. The method according to claim 1, wherein the batch normalization operation comprises translation parameters and scaling parameters, the LSTM layer comprises an input gate, a forget gate, and an output gate, and the batch normalization operations are performed to weight parameters of the input gate, the forget gate, and the output gate to obtain an optimized generator and discriminator.

3. The method according to claim 1, further comprising: replacing a cross entropy loss function of TimeGAN by a mean square error MSE.

4. The method according to claim 1, wherein the step of using the critical safety distance model to calculate an initial state of the autonomous driving vehicle under test corresponding to each lane change background vehicle is performed by the following formulas:
$${d}_{min} = {\int }_{0}^{{t}_{C}} {\int }_{0}^{{t}_{C}} {a}_{a v} ( t ) {d}^{2} t - 2 \times l \times cos ( θ ( {t}_{C} ) ) + l \times cos ( θ ( {t}_{T} ) )$$
$${v}_{a v} = {v}_{h v} + {\int }_{0}^{{t}_{C}} {a}_{a v} ( t ) dt$$
$$S = {y}_{lat} ( {t}_{C} ) - l \times sin ( θ ( {t}_{C} ) )$$
$${a}_{a v} ( t ) = \{ \begin{matrix}k \times {a}_{max} \times t , 0 < t \leq {t}_{1} \\ {a}_{max} , {t}_{1} < t \leq {t}_{T}\end{matrix}$$
where, dₘᵢₙ is a minimum safe distance between the autonomous driving vehicle under test and the lane change background vehicle, vₐᵥ is an initial speed of the autonomous driving vehicle under test, S is an initial lateral distance between the autonomous driving vehicle under test and the lane change background vehicle, C is a critical point where the lane change background vehicle and the autonomous driving vehicle under test reach a critical state without collision, t_{C} is a time required for the lane change background vehicle to reach the point C, t is time, d²t represents double integral of acceleration aₐᵥ with respect to t, t_{T} is the moment when the lane change background vehicle and the autonomous driving vehicle under test maintain the same speed, l is a length of the lane change background vehicle, θ(t_{C}) is a lane-changing angle of the autonomous driving vehicle under test at time t_{C}, calculated based on a relative relationship between the lateral positions of the vehicles, similarly, θ(t_{T}) is a lane-changing angle of the autonomous driving vehicle under test at time t_{T}, yₗₐₜ(t_{C}) represents a lateral position of the lane change background vehicle at time t_{C}, vₕᵥ is an average speed of the lane change background vehicle, aₐᵥ(t) is an acceleration of the autonomous driving vehicle under test at time t, k is a slope of acceleration change of the lane change background vehicle, aₘₐₓ represents a maximum braking acceleration of the autonomous driving vehicle under test, and t₁ represents a time for a braking acceleration of the autonomous driving vehicle under test to change from 0 to the maximum braking acceleration.

5. The method according to claim 1, wherein the numbers of LSTM layers of the generator and the discriminator of the risky lane change trajectory generation model Traj-TimeGAN are both three.

6. The method according to claim 3, wherein the loss function in the risky lane change trajectory generation model Traj-TimeGAN further comprises a style loss function s_loss, and the style loss function s_loss is expressed as:
$${s\_loss = ‖ D\_s ( {X}_{1 : N} , N ) ) - D\_s ( G ( E ( {X}_{1 : N} , N ) , N ) , N ) ‖}_{2}$$
where, D_s(⋅) is a time discriminator, G(⋅) is a generator, E(⋅) is an encoder, X_{1:N} represents a feature matrix of intermediate states generated for various time steps, N represents a time step, and a length of the feature matrix generated for various time steps is also N, ∥⋅∥₂ represents the two-norm, which is used to represent a length or modulus of a vector.

7. The method according to claim 6, wherein the loss function in the risky lane change trajectory generation model Traj-TimeGAN further comprises a discriminator loss function d_loss, and the discriminator loss function d_loss is expressed as:
$${d\_loss = ‖ D ( {X}_{1 : N} , N ) ) - D ( G ( E ( {X}_{1 : N} , N ) , N ) , N ) ‖}_{2}$$
where, D(⋅) is a discriminator, G(⋅) is a generator, E(⋅) is an encoder, X_{1:N} represents a feature matrix of intermediate states generated for various time steps, N represents a time step, and a length of the feature matrix generated for various time steps is also N, ∥⋅∥₂ represents the two-norm, which is used to represent a length or modulus of a vector.

8. A test scenario generation system for risky lane-changing tests during autonomous driving, comprising:
a data set acquisition assembly, configured for obtaining a real risky lane change trajectory set;
a model construction assembly, configured for generating an adversarial network TimeGAN based on time series, expanding the number of LSTM layers of a long short-term memory network of a generator and discriminator of TimeGAN, and introducing one batch normalization operation for each LSTM layer, and then using a random deactivation Dropout layer to randomly discard half of an output of the LSTM layer, and finally using a fully connected layer for output, and obtaining a probability of each output category through a softmax operation to obtain a constructed risky lane change trajectory generation model Traj-TimeGAN;
a lane change vehicle trajectory acquisition assembly, configured for inputting the data in the real risky lane change trajectory set into Traj-TimeGAN, and obtaining a lane change trajectory of a lane change background vehicle with human driving characteristics;
a safety distance model construction assembly, configured for analyzing safety constraint conditions of an autonomous driving vehicle and constructing a critical safety distance model for the vehicle;
a test scenario generation assembly, configured for using the critical safety distance model to calculate an initial state of the autonomous driving vehicle under test corresponding to each lane change background vehicle; combining the lane change trajectory of each lane change background vehicle and the initial state of the autonomous driving vehicle under test corresponding to each lane change background vehicle to construct a critical lane change scenario test case, and generating critical lane change test scenarios corresponding to all risky lane change trajectories through scenario generalization.

9. A computer device, comprising a memory and a processor, wherein the memory stores a computer program, and the processor is configured to run the computer program in the memory to execute the test scenario generation method for risky lane-changing test of autonomous driving.
